(19) United States
(12) Patent Application Publication
(10) Pub. No.: US 2023/0197721 A1
(43) Pub. Date: Jun. 22, 2023

(54) WAFER BONDING FOR STACKED TRANSISTORS

(71) Applicant: International Business Machines Corporation, Armonk, NY (US)

(72) Inventors: Ruqiang Bao, Niskayuna, NY (US); Michael P. Belyansky, Halfmoon, NY (US); Dechao Guo, Niskayuna, NY (US); Junli Wang, Slingerlands, NY (US)

(21) Appl. No.: 17/553,967

(22) Filed: Dec. 17, 2021

(51) Int. Cl. H01L 27/092; H01L 29/78; H01L 29/423; H01L 29/786; H01L 29/06; H01L 29/04; H01L 23/00

(52) U.S. Cl. CPC H01L 27/092; H01L 27/0922; H01L 27/0924; H01L 29/785; H01L 29/42392; H01L 29/78696; H01L 29/0665; H01L 29/045; H01L 24/83; H01L 2224/83896

(57) ABSTRACT

Embodiments of the present invention are directed to processing methods and resulting structures that leverage wafer bonding techniques to provide stacked field effect transistors (SFETs) with high-quality N/P junction isolation. In a non-limiting embodiment of the invention, a first semiconductor structure is formed on a first wafer and a second semiconductor structure is formed on a second wafer. The first wafer is positioned with respect to the second wafer such that a top surface of the first semiconductor structure is directly facing a top surface of the second semiconductor structure. A bonding layer is formed between the top surface of the first semiconductor structure and the top surface of the second semiconductor structure and the first wafer is bonded to the second wafer at a first temperature. The device is annealed at a second temperature to cure the bonding layer. The anneal temperature is greater than the bonding temperature.

### BACKGROUND

The present invention generally relates to fabrication methods and resulting structures for semiconductor devices, and more specifically, to processing methods and resulting structures that leverage wafer bonding to provide stacked field effect transistors (SFETs).

Known metal oxide semiconductor field effect transistor (MOSFET) fabrication techniques include process flows for constructing planar field effect transistors (FETs). A planar FET includes a substrate (also referred to as a silicon slab); a gate formed over the substrate; source and drain regions formed on opposite ends of the gate; and a channel region near the surface of the substrate under the gate. The channel region electrically connects the source region to the drain region while the gate controls the current in the channel. The gate voltage controls whether the path from drain to source is an open circuit (“off”) or a resistive path (“on”).

In recent years, research has been devoted to the development of nonplanar transistor architectures. For example, nanosheet FETs include a non-planar architecture that provides increased device density and some increased performance over lateral devices. In nanosheet FETs, in contrast to conventional planar FETs, the channel is implemented as a plurality of stacked and spaced-apart nanosheets. The gate stack wraps around the full perimeter of each nanosheet, thus enabling fuller depletion in the channel region, and also reducing short-channel effects due to steeper subthreshold swing (SS) and smaller drain induced barrier lowering (DIBL).

### SUMMARY

Embodiments of the invention are directed to a method for forming a stacked semiconductor device with high-quality N/P junction isolation. A non-limiting example of the method includes forming a first semiconductor structure on a first wafer and forming a second semiconductor structure on a second wafer. The first wafer is positioned with respect to the second wafer such that a top surface of the first semiconductor structure is directly facing a top surface of the second semiconductor structure. A bonding layer is formed between the top surface of the first semiconductor structure and the top surface of the second semiconductor structure. The first wafer is bonded to the second wafer at a first temperature and the structure is annealed at a second temperature to cure the bonding layer. The second temperature is greater than the first temperature.

Embodiments of the invention are directed to a stacked semiconductor structure. A non-limiting example of the semiconductor structure includes a fin-type semiconductor structure. The fin-type semiconductor structure includes one or more semiconductor fins and a first gate formed over channel regions of the one or more semiconductor fins. A bonding layer is formed over the fin-type semiconductor structure. The structure further includes a gate all around (GAA) nanosheet structure. The GAA nanosheet structure includes a nanosheet stack formed over the bonding layer and a second gate formed over channel regions of the nanosheet stack.

Embodiments of the invention are directed to a stacked semiconductor structure. A non-limiting example of the semiconductor structure includes a first GAA nanosheet structure. The first GAA nanosheet structure includes a first nanosheet stack and a first gate formed over channel regions of the first nanosheet stack. A bonding layer is formed over the first GAA nanosheet structure. The structure includes a second GAA nanosheet structure. The second GAA nanosheet structure includes a second nanosheet stack formed over the bonding layer and a second gate formed over channel regions of the second nanosheet stack.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a cross-sectional view of a first wafer after an initial set of processing operations according to one or more embodiments of the invention;

FIG. 1B depicts a cross-sectional view of a second wafer after an initial set of processing operations according to one or more embodiments of the invention;

FIG. 1C depicts a cross-sectional view of the first wafer after a processing operation according to one or more embodiments of the invention;

FIG. 1D depicts a cross-sectional view of the second wafer after a processing operation according to one or more embodiments of the invention;

FIG. 1E depicts a cross-sectional view of the first wafer and the second wafer after a wafer bonding operation according to one or more embodiments of the invention;

FIG. 1F depicts a cross-sectional view of the first wafer and the second wafer after a processing operation according to one or more embodiments of the invention;

FIG. 2A depicts a cross-sectional view (parallel to gate) of an SFET formed after completing the wafer bonding process illustrated in FIGS. 1A to 1F;

FIG. 2B depicts a cross-sectional view (across gate) of the SFET after completing the wafer bonding process illustrated in FIGS. 1A to 1F;

FIG. 3A depicts a cross-sectional view of a first wafer after an initial set of processing operations according to one or more embodiments of the invention;

FIG. 3B depicts a cross-sectional view of a second wafer after an initial set of processing operations according to one or more embodiments of the invention;

FIG. 3C depicts a cross-sectional view of the first wafer after a processing operation according to one or more embodiments of the invention;

FIG. 3D depicts a cross-sectional view of the second wafer after a processing operation according to one or more embodiments of the invention;

FIG. 3E depicts a cross-sectional view of the first wafer and the second wafer after a wafer bonding operation according to one or more embodiments of the invention;

FIG. 3F depicts a cross-sectional view of the first wafer and the second wafer after a processing operation according to one or more embodiments of the invention;

FIG. 4A depicts a cross-sectional view (parallel to gate) of an SFET formed after completing the wafer bonding process illustrated in FIGS. 3A to 3F;

FIG. 4B depicts a cross-sectional view (across gate) of the SFET after completing the wafer bonding process illustrated in FIGS. 3A to 3F;

FIG. 5A depicts a cross-sectional view of a first wafer after an initial set of processing operations according to one or more embodiments of the invention;

FIG. 5B depicts a cross-sectional view of a second wafer after an initial set of processing operations according to one or more embodiments of the invention;

FIG. 5C depicts a cross-sectional view of the first wafer after a processing operation according to one or more embodiments of the invention;

FIG. 5D depicts a cross-sectional view of the second wafer after a processing operation according to one or more embodiments of the invention;

FIG. 5E depicts a cross-sectional view of the first wafer and the second wafer after a wafer bonding operation according to one or more embodiments of the invention;

FIG. 5F depicts a cross-sectional view of the first wafer and the second wafer after a processing operation according to one or more embodiments of the invention;

FIG. 6A depicts a cross-sectional view (parallel to gate) of an SFET formed after completing the wafer bonding process illustrated in FIGS. 5A to 5F;

FIG. 6B depicts a cross-sectional view (across gate) of the SFET after completing the wafer bonding process illustrated in FIGS. 5A to 5F;

FIG. 7A depicts a cross-sectional view of a first wafer after an initial set of processing operations according to one or more embodiments of the invention;

FIG. 7B depicts a cross-sectional view of a second wafer after an initial set of processing operations according to one or more embodiments of the invention;

FIG. 7C depicts a cross-sectional view of the first wafer after a processing operation according to one or more embodiments of the invention;

FIG. 7D depicts a cross-sectional view of the second wafer after a processing operation according to one or more embodiments of the invention;

FIG. 7E depicts a cross-sectional view of the first wafer and the second wafer after a wafer bonding operation according to one or more embodiments of the invention;

FIG. 7F depicts a cross-sectional view of the first wafer and the second wafer after a processing operation according to one or more embodiments of the invention;

FIG. 8A depicts a cross-sectional view (parallel to gate) of an SFET formed after completing the wafer bonding process illustrated in FIGS. 7A to 7F;

FIG. 8B depicts a cross-sectional view (across gate) of the SFET after completing the wafer bonding process illustrated in FIGS. 7A to 7F;

FIG. 9 depicts a flow diagram illustrating a method according to one or more embodiments of the invention;

FIG. 10 depicts a flow diagram illustrating a method according to one or more embodiments of the invention; and

FIG. 11 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

There are a few candidates for scaling nonplanar transistors beyond the 7 nm node, but each is currently limited due to various factors. One proposed candidate is the so-called stacked field effect transistor (SFET), sometimes referred to as a stackFET. To increase the available computing power per unit area, SFET devices vertically stack two semiconductor devices over a shared substrate footprint. SFET fabrication is challenging, however, and efforts are ongoing to design SFET fabrication schemes and structures that are suitable for scaled production. One challenge is the difficulty in forming a high-quality N/P junction isolation layer between SFET devices in a SFET fabrication flow. Low quality N/P junction insolation layers erode during SFET fabrication and are formed to higher thicknesses to compensate. The result is a final device with weakened structural integrity and reduced performance.

Turning now to an overview of aspects of the present invention, one or more embodiments of the invention address the above-described shortcomings by providing fabrication methods and resulting structures that leverage wafer bonding techniques to provide SFETs with high-quality N/P junction isolation. A high-quality isolation layer resists erosion during SFET fabrication and allows for the isolation layer thickness to be reduced. Reducing the N/P junction isolation layer thickness lowers the wiring resistance of the device interconnect, which is used to connect the stacked top transistor and bottom transistor, to improve the performance. To achieve high-quality N/P junction isolation, the SFET is formed from two wafers (one nFET, one pFET) that are later bonded, rather than monolithically. A bonding layer is formed between the wafers, which serves as both the bonding agent and as an isolation layer between the nFET/pFET wafers.

Rather than relying upon conventional bonding layers of relatively low oxide quality (e.g., a low temperature oxide (LTO) at less than 400 degrees Celsius) or low bonding strength (e.g., thermal oxides at temperatures over 1000 degree Celsius), a high-quality, high-strength bonding layer is built by leveraging a combination of material selection, bonding surface pretreatments, and anneal temperature treatments. In some embodiments of the invention, two wafers are initially bonded together using a bonding oxide at relatively low temperatures (i.e., temperatures less than 400 degrees Celsius) to ensure a high-strength bond. After the wafers are bonded, the bonding oxide is annealed at an intermediate temperature (e.g., 700 degrees Celsius RTA, 500-600 degrees Celsius furnace anneal) to improve oxide quality while still allowing for high-quality bonding. In some embodiments of the invention, one or both wafers are pretreated with a prolonged (e.g., greater than 10 minutes) DI water treatment, typically used just before bonding, to convert the respective wafer surface(s) to a more hydrophilic state.

Alternatively, or in addition, a high-density plasma (HDP) oxide can be used as the bonding oxide (or as an additional insulator layer in a multi-layer bonding structure). While deposited at relatively low temperatures (i.e., less than 500 degrees Celsius), HDP oxide is very high quality, provides low leakage, and is well-suited to isolation applications. Moreover, HDP oxide contains a high concentration of hydrogen that results in silanol (Si—OH) groups at the bonding interface that are beneficial for bonding forming. In some embodiments of the invention, a separate insulator layer is deposited on one or both wafers prior to depositing the bonding layer. These insulator layers, if present, can be made of high-quality oxide materials (e.g., an HDP oxide) and can serve as the substrate upon which the bonding layer can be formed. In some embodiments of the invention, other dielectrics (e.g., SiN, SiOC, etc.) can be built on top of, or in place of, the bonding oxide in the bonding structure (i.e., an insulator-bonding layer-insulator stack).

Advantageously, building an SFET from two wafers according to one or more embodiments affords flexibility with respect to the underlying device types incorporated within the SFET structure. For example, a top wafer can be configured for nanosheets, while a bottom wafer can be configured for fins (or vice versa). Alternatively, both top and bottom wafers can be configured for nanosheets (or fins), albeit with differently orientated crystalline surfaces. For example, the top wafer can include <100> nanosheets (or fins), while the bottom wafer can include <110> nanosheets (or fins), or vice versa. In short, hybrid SFETs can be built with a variety of configurations by changing the incoming structure of each respective wafer. While discussed with reference to nanosheets and fins for convenience, SFETs built according to one or more embodiments need not be so limited, and can include other transistor architectures (vertical FETs, Comb-NS, etc.).

Other advantages include a relatively thin bonding layer (with respect, e.g., to conventional LTOs). While typical oxides are formed to a thickness of 500 nm or more, the minimum thickness of bonding oxides formed according to one or more embodiments is limited only by the deposition and planarization (e.g., chemical-mechanical planarization (CMP)) techniques employed. Consequently, it is possible to form arbitrarily thin bonding oxide layers without losing oxide quality or bonding strength. For example, a bonding oxide layer can be initially deposited to a thickness of 10, 20, 30, 40, 50, 60, 70, 80, 90, 100 nm, and thinned (grinded) by CMP by 5 to 30 nm to provide a final thickness bonding oxide thickness of 5 to 70 nm, for example, 30 nm.

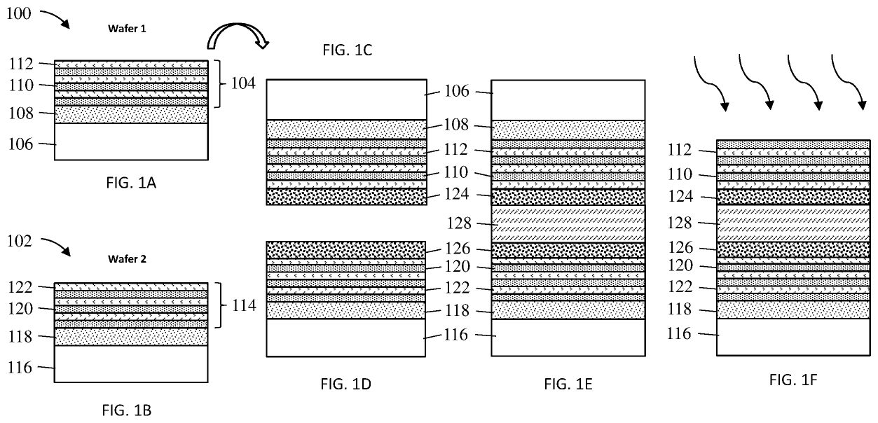

Turning now to a more detailed description of fabrication operations and resulting structures according to aspects of the invention, FIGS. 1A and 1B depict cross-sectional views of a first semiconductor wafer 100 (“Wafer 1”) and a second semiconductor wafer 102 (“Wafer 2”), respectively, after an initial set of fabrication operations have been applied as part of a method of fabricating a final semiconductor device according to one or more embodiments of the invention.

As shown in FIG. 1A, a nanosheet stack 104 is formed over a substrate 106 in the first semiconductor wafer 100. The substrate 106 can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlInAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments of the invention, the substrate 106 can include a silicon-on-insulator (SOI) layer 108. The SOI layer 108 includes a silicon layer formed on a buried oxide layer (the silicon layer and buried oxide are not separately shown). The buried oxide layer can be made of any suitable dielectric material, such as, for example, a silicon oxide. In some embodiments of the invention, the buried oxide layer is formed to a thickness of about 10-200 nm, although other thicknesses are within the contemplated scope of the invention.

As further shown in FIG. 1A, the nanosheet stack 104 can include one or more semiconductor layers 110 alternating with one or more sacrificial layers 112. In some embodiments of the invention, the semiconductor layers 110 and the sacrificial layers 112 are epitaxially grown layers. For ease of discussion reference is made to operations performed on and to a nanosheet stack having three nanosheets (e.g., the three semiconductor layers 110 shown in FIG. 1A) alternating with three sacrificial layers (e.g., the three sacrificial layers 112). It is understood, however, that the nanosheet stack 104 can include any number of nanosheets alternating with a corresponding number of sacrificial layers. For example, the nanosheet stack 104 can include two nanosheets, five nanosheets, eight nanosheets, 30 nanosheets (e.g., 3D NAND), or any number of nanosheets, along with a corresponding number of sacrificial layers (i.e., as appropriate to form a nanosheet stack having a topmost sacrificial layer and a sacrificial layer between each pair of adjacent nanosheets).

The semiconductor layers 110 can be made of any suitable material such as, for example, monocrystalline silicon or silicon germanium. In some embodiments of the invention, the semiconductor layers 110 are silicon nanosheets. In some embodiments of the invention, the semiconductor layers 110 have a thickness of about 4 nm to about 10 nm, for example 6 nm, although other thicknesses are within the contemplated scope of the invention. In some embodiments of the invention, the substrate 106 and the semiconductor layers 110 can be made of a same semiconductor material. In other embodiments of the invention, the substrate 106 can be made of a first semiconductor material, and the semiconductor layers 110 can be made of a second, different semiconductor material.

The sacrificial layers 112 can be silicon or silicon germanium layers, depending on the material of the semiconductor layers 110 to meet etch selectivity requirements. For example, in embodiments where the semiconductor layers 110 are silicon nanosheets, the sacrificial layers 112 can be silicon germanium layers. In embodiments where the semiconductor layers 110 are silicon germanium nanosheets, the sacrificial layers 112 can be silicon germanium layers having a germanium concentration that is greater than the germanium concentration in the semiconductor layers 110. For example, if the semiconductor layers 110 are silicon germanium having a germanium concentration of 5 percent (sometimes referred to as SiGe5), the sacrificial layers 112 can be silicon germanium layers having a germanium concentration of about 25 (SiGe25), although other germanium concentrations are within the contemplated scope of the invention. In some embodiments of the invention, the sacrificial layers 112 have a thickness of about 8 nm to about 15 nm, for example 10 nm, although other thicknesses are within the contemplated scope of the invention.

As shown in FIG. 1B, a second nanosheet stack 114 is formed over a substrate 116 in the second semiconductor wafer 102. The second nanosheet stack 114 and the substrate 106 can be made of similar materials and in a similar manner as the first nanosheet stack 104 and the substrate 106 discussed previously with respect to the first semiconductor wafer 100. In some embodiments of the invention, the substrate 116 can include an SOI layer 118, in a similar manner as the SOI layer 108.

In some embodiments of the invention, the first nanosheet stack 104 and the second nanosheet stack 114 include a same number of semiconductor layers. In some embodiments of the invention, the first nanosheet stack 104 can have more, or fewer, semiconductor layers than the second nanosheet stack 114. In some embodiments of the invention, the semiconductor layers 120 are made of a same material as the semiconductor layers 110. In some embodiments of the invention, the semiconductor layers 110 are made of a first semiconductor material and the semiconductor layers 120 are made of a second semiconductor material. For example, the semiconductor layers 110 can be silicon layers and the semiconductor layers 120 can be silicon germanium layers (or vice versa). The semiconductor layers 110 and 120 can be formed to a same (or different) thickness, depending on the application. Similarly, the sacrificial layers 112 and 122 can be formed to a same (or different thickness), as desired.

In some embodiments of the invention, the first nanosheet stack 104 and the second nanosheet stack 114 include semiconductor materials having a same crystalline orientation. For example, the semiconductor layers 110 and 120 can be silicon layers having a <100> orientation (or <110>, <111>, etc.). In some embodiments of the invention, the semiconductor layers 110 are epitaxially grown at a first crystalline orientation and the semiconductor layers 120 are epitaxially grown at a second crystalline orientation. For example, the semiconductor layers 110 can be <100> silicon layers and the semiconductor layers 120 can be <110> silicon layers (or vice versa). Crystalline orientation and semiconductor materials can be varied simultaneously. For example, the semiconductor layers 110 can be <100> silicon layers and the semiconductor layers 120 can be <110> silicon germanium layers (or vice versa). In some embodiments of the invention, the crystalline orientation for the NFET comprises a <100> crystalline orientation and the crystalline orientation for the PFET comprises a <110> crystalline orientation.

FIGS. 1C and 1D depict cross-sectional views of the first semiconductor wafer 100 and the second semiconductor wafer 102, respectively, after a processing operation according to one or more embodiments of the invention. As shown FIG. 1C, an insulator layer 124 can be formed on a surface of the first nanosheet stack 104. In some embodiments of the invention, the insulator layer 124 includes a high-quality oxide material such as, for example, an HDP oxide. The insulator layer 124 can be formed to a thickness of about 10-200 nm, although other thicknesses are within the contemplated scope of the invention. As further shown FIG. 1C, the first semiconductor wafer 100 can be flipped so that the insulator layer 124 is oriented towards the second semiconductor wafer 102.

As shown FIG. 1D, an insulator layer 126 can be formed on a surface of the second nanosheet stack 114. The insulator layer 126 can be formed of similar materials and in a similar manner as the insulator layer 124 previously discussed with respect to FIG. 1C. In some embodiments of the invention, the insulator layer 126 includes a high-quality oxide material such as, for example, an HDP oxide. The insulator layer 126 can be formed to a thickness of about 10-200 nm, although other thicknesses are within the contemplated scope of the invention.

FIG. 1E depicts a cross-sectional view of the first semiconductor wafer 100 and the second semiconductor wafer 102 after a wafer bonding operation according to one or more embodiments of the invention. As shown FIG. 1E, a bonding layer 128 can be bonded to opposing surfaces of the insulator layers 124 and 126, thereby bonding the first semiconductor wafer 100 to the second semiconductor wafer 102. The bonding layer 128 can include one or more of an oxide, a nitride, silicon nitride, SiOC, and SiBCN. In some embodiments of the invention, the bonding layer 128 includes a bonding oxide formed at a low temperature (i.e., less than 400 degrees Celsius). In some embodiments of the invention, one or both of the optional insulator layers 124 and 126 are skipped and the bonding layer 128 is bonded directly to one or both of the nanosheet stacks 104 and 114.

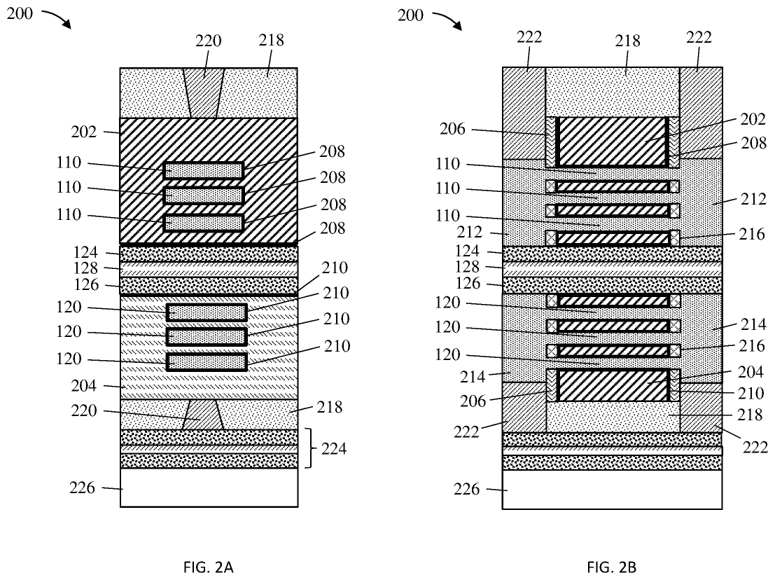

While shown as having a single bonding layer 128 for ease of discussion and illustration, it should be understood that any number of additional wafers (not separately shown) can be similarly bonded to either exposed end of the combined first semiconductor wafer 100 and second semiconductor wafer 102. For example, a second (or third, etc.) bonding stack including a bonding layer and one or both optional insulator layers can be formed at either end of the combined first semiconductor wafer 100 and second semiconductor wafer 102 at any stage of fabrication (immediately after the process operations shown in FIGS. 1E or 1F, after forming one or more gate stacks, after forming contacts, etc.) to bond additional wafers to the structure. In this manner, an SFET can be built having any number of vertically integrated semiconductor devices. In some embodiments of the invention, an additional wafer (also referred to as a handling substrate) is bonded to one end of the combined first semiconductor wafer 100 and second semiconductor wafer 102 (as shown, for example, in FIGS. 2A and 2B).

In some embodiments of the invention, the surface(s) upon which the bonding layer 128 is formed are pretreated with a prolonged (e.g., greater than 10 minutes) DI water treatment, typically used just before bonding, to convert the respective wafer surface(s) to a more hydrophilic state. Other pretreatment techniques can be used in addition or, or alternatively to, the DI water treatment. Bonding insulator treatments can include, for example, argon or oxygen plasma treatments and/or an ultraviolet (UV) cure to reduce outgassing and to reduce the number of dangling bonds (which are more hydrophobic) at the bonding interface surface.

FIG. 1F depicts a cross-sectional view of the first semiconductor wafer 100 and the second semiconductor wafer 102 after a processing operation according to one or more embodiments of the invention. As shown FIG. 1F, the bonding layer 128 can be annealed at an intermediate temperature (e.g., 700 degrees Celsius RTA, 500-600C furnace anneal, etc.). As used herein, an “intermediate” temperature refers to a temperature above 400 degrees Celsius (low temperatures) and below 1000 degrees Celsius (high temperatures). Annealing cures the bonding layer 128, improving oxide quality.

In some embodiments of the invention, the SOI layer 108 and the substrate 106 of the first semiconductor wafer 100 are removed to expose a surface of the nanosheet stack 104. The SOI layer 108 and the substrate 106 of the first semiconductor wafer 100 can be removed using, for example, a CMP process, wafer grinding, or a combination of wet and/or dry etches.

After wafer grinding (or CMP, etc.) is complete, the combined first semiconductor wafer 100 and second semiconductor wafer 102 can be finalized using known FEOL, MOL, and BEOL processes to define the final SFET device. For example, the final SFET device can be assembled by building a first transistor using the exposed nanosheet stack 104, bonding a third wafer to the first transistor, flipping over the combined wafer, removing the bottom substrate to expose the nanosheet stack 114, and building the second transistor using the exposed nanosheet stack 114. FIGS. 2A and 2B depict cross-sectional views (parallel to gate and across gate, respectively) of an SFET 200 formed after completing the wafer bonding process discussed previously with respect to FIGS. 1A to 1F.

As shown in FIGS. 2A and 2B, the SFET 200 includes the semiconductor layers 110 and 120, the bonding layer 128, and the insulator layers 124, 126. Known FEOL processes have been carried out to form a top gate 202 over channel regions of the semiconductor layers 110 and a bottom gate 204 over channel regions of the semiconductor layers 120. As used herein, the “channel region” refers to the portion of the semiconductor layers 110, 120 over which the gates 202, 204 are formed, and through which current passes from source to drain in the final device.

In some embodiments of the invention, the gates 202 and 204 are high-k metal gates (HKMGs) formed using known replacement metal gate (RMG) processes, or so-called gate-first processes. For example, a sacrificial gate (not separately shown) can be formed between gate spacers 206 and later removed, along with the sacrificial layers 112 and 122, to release the semiconductor layers 110 and 120 (once released, the semiconductor layers 110 and 120 are often referred to as nanosheets or channels). The gates 202 and 204 can then be formed over the released semiconductor layers 110 and 120.

In some embodiments of the invention, the gates 202 and 204 can include gate dielectrics 208, 210 respectively, and work function metal stacks (not separately depicted). In some embodiments of the invention, the gate dielectrics 208, 210 are high-k dielectric films formed on respective surfaces (sidewalls) of the semiconductor layers 110, 120. The high-k dielectric film can be made of, for example, silicon oxide, silicon nitride, silicon oxynitride, boron nitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials can further include dopants such as lanthanum and aluminum. In some embodiments of the invention, the high-k dielectric film can have a thickness of about 0.5 nm to about 4 nm. In some embodiments of the invention, the high-k dielectric film includes hafnium oxide and has a thickness of about 1 nm, although other thicknesses are within the contemplated scope of the invention.

The work function metal stack, if present, can include one or more work function layers positioned between the high-k dielectric film and a bulk gate material. In some embodiments of the invention, the gates 202 and 204 includes one or more work function layers, but do not include a bulk gate material. The work function layers can be made of, for example, aluminum, lanthanum oxide, magnesium oxide, strontium titanate, strontium oxide, titanium nitride, tantalum nitride, hafnium nitride, tungsten nitride, molybdenum nitride, niobium nitride, hafnium silicon nitride, titanium aluminum nitride, tantalum silicon nitride, titanium aluminum carbide, tantalum carbide, and combinations thereof. The work function layers can serve to modify the work function of the gates 202 and 204 and enables tuning of the device threshold voltage. In some embodiments of the invention, the work function layers for the gates 202 and 204 are of opposite type (e.g., one nFET work function layer(s) and one pFET work function layer(s)). The work function layers can be formed to a thickness of about 0.5 to 6 nm, although other thicknesses are within the contemplated scope of the invention. In some embodiments of the invention, each of the work function layers can be formed to a different thickness.

In some embodiments, the gates 202 and 204 include a main body formed from bulk conductive gate material(s) deposited over the work function layers and/or gate dielectrics. The bulk gate material can include any suitable conducting material, such as, for example, metal (e.g., tungsten, titanium, tantalum, ruthenium, zirconium, cobalt, copper, aluminum, lead, platinum, tin, silver, gold), conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), conductive carbon, graphene, or any suitable combination of these materials. The conductive gate material can further include dopants that are incorporated during or after deposition.

As further shown in FIGS. 2A and 2B, top source and drain regions 212 and bottom source and drain regions 214 can be formed on exposed sidewalls of the semiconductor layers 110 and 120, respectively. The source and drain regions 212, 214 can be epitaxially grown using, for example, vapor-phase epitaxy (VPE), molecular beam epitaxy (MBE), liquid-phase epitaxy (LPE), or other suitable processes. The source and drain regions 212, 214 can be semiconductor materials epitaxially grown from gaseous or liquid precursors. In some embodiments of the invention, the gas source for the epitaxial deposition of semiconductor material includes a silicon containing gas source, a germanium containing gas source, or a combination thereof. For example, a silicon layer can be epitaxially deposited (or grown) from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. A germanium layer can be epitaxially deposited from a germanium gas source that is selected from the group consisting of germane, digermane, halogermane, dichlorogermane, trichlorogermane, tetrachlorogermane and combinations thereof. A silicon germanium alloy layer can be epitaxially formed utilizing a combination of such gas sources. Carrier gases like hydrogen, nitrogen, helium and argon can be used. In some embodiments of the invention, the epitaxial semiconductor materials include carbon doped silicon (Si:C). This Si:C layer can be grown in the same chamber used for other epitaxy steps or in a dedicated Si:C epitaxy chamber. The Si:C can include carbon in the range of about 0.2 percent to about 3.0 percent.

Epitaxially grown silicon and silicon germanium can be doped by adding n-type dopants (e.g., P or As) or p-type dopants (e.g., Ga, B, BF₂, or Al) as desired. In some embodiments of the invention, the source and drain regions 212 are n-type source and drain regions while the source and drain regions 214 are p-type source and drain regions (or vice versa). In some embodiments of the invention, the source and drain regions 212, 214 can be epitaxially formed and doped by a variety of methods, such as, for example, in-situ doped epitaxy (doped during deposition), doped following the epitaxy, or by implantation and plasma doping. The dopant concentration in the doped regions can range from 1×10¹⁹ cm⁻³ to 2×10²¹ cm⁻³, or between 1×10²⁰ cm⁻³ and 1×10²¹ cm⁻³.

In some embodiments of the invention, the sacrificial layers 112 and 122 can be recessed (prior to operations shown in FIGS. 2A and 2B) and inner spacers 216 can be formed on the recessed sidewalls of the sacrificial layers 112 and 122. For example, sidewalls of the sacrificial layers 112 and 122 can be recessed to form cavities (not shown) that are filled with dielectric material to define the inner spacers 216. In some embodiments of the invention, portions of the inner spacers 216 that extend beyond sidewalls of the nanosheet stacks 104 and 114 are removed, using, for example, an isotropic etching process. In this manner, sidewalls of the inner spacers 216 can be coplanar to sidewalls of the semiconductor layers 110 and 120. In some embodiments of the invention, the inner spacers 216 are formed using a chemical vapor deposition (CVD), plasma enhanced CVD (PECVD), atomic layer deposition (ALD), physical vapor deposition (PVD), chemical solution deposition, or other like processes in combination with a wet or dry etch process. The inner spacers 216 can be made of any suitable material, such as, for example, a low-k dielectric, a nitride, silicon nitride, silicon dioxide, SiON, SiC, SiOCN, or SiBCN.

As further shown in FIGS. 2A and 2B, an interlayer dielectric (ILD) 218 can be formed over one or both ends of the combined first semiconductor wafer 100 and second semiconductor wafer 102. The ILD 218 can be made of any suitable dielectric material, such as, for example, oxides, a low-k dielectric, nitrides, silicon nitride, silicon oxide, SiON, SiC, SiOCN, and SiBCN.

In some embodiments of the invention, the ILD 218 can be removed (patterned) to form contact trenches (not separately shown) which can be filled with conductive material to define gate contacts 220 and source/drain contacts 222.

The gate contacts 220 and source/drain contacts 222 can be formed from conductive materials that include copper or a non-copper metal (e.g., tungsten, titanium, tantalum, ruthenium, zirconium, cobalt, aluminum, platinum), alloys thereof, conducting metallic compound material (e.g., tantalum nitride, titanium nitride, tantalum carbide, titanium carbide, titanium aluminum carbide, tungsten silicide, tungsten nitride, cobalt silicide, nickel silicide), conductive carbon, or any suitable combination of these materials. In some embodiments of the invention, the gate contacts 220 and source/drain contacts 222 are formed of a same conductive material, for example, cobalt, copper, ruthenium, or tungsten. In some embodiments of the invention, the gate contacts 220 and source/drain contacts 222 are made of different conductive materials. In some embodiments of the invention, one or more of the gate contacts 220 and source/drain contacts 222 includes a barrier liner (sometimes referred to as a metal liner, or barrier metal liner) to prevent diffusion into surrounding dielectrics (not shown).

In some embodiments of the invention, a second bonding structure 224 is formed on one end of the SFET 200. The second bonding structure 224 can include a bonding layer and one or two insulator layers in a similar manner as the bonding layer 128 and the insulator layers 124, 126 described previously. In some embodiments of the invention, the second bonding structure 224 is leveraged to bond an additional wafer 226 to the SFET 200. In some embodiments of the invention, the wafer 226 is a handling wafer (or handling substrate).

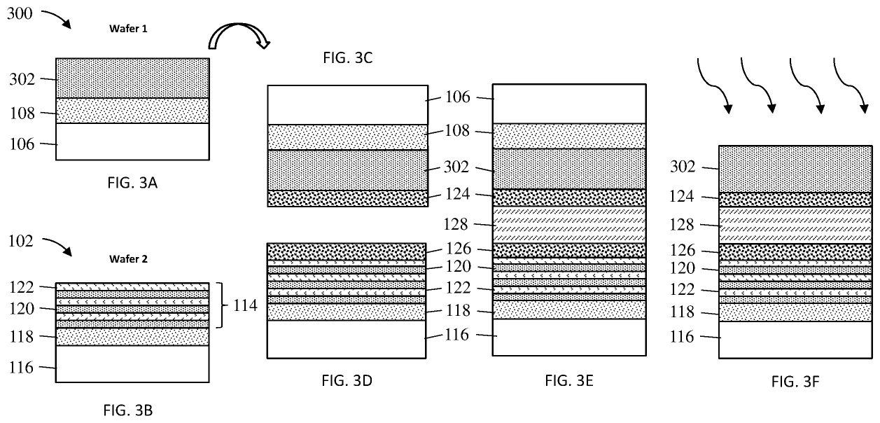

FIGS. 3A and 3B depict cross-sectional views of a first semiconductor wafer 300 (“Wafer 1”) and the second semiconductor wafer 102 (“Wafer 2”), respectively, after an initial set of fabrication operations have been applied as part of a method of fabricating a final semiconductor device according to one or more embodiments of the invention. FIGS. 3A and 3B illustrate a similar embodiment to that shown in FIGS. 1A and 1B, except that the first semiconductor wafer 300 has been swapped for the first semiconductor wafer 100.

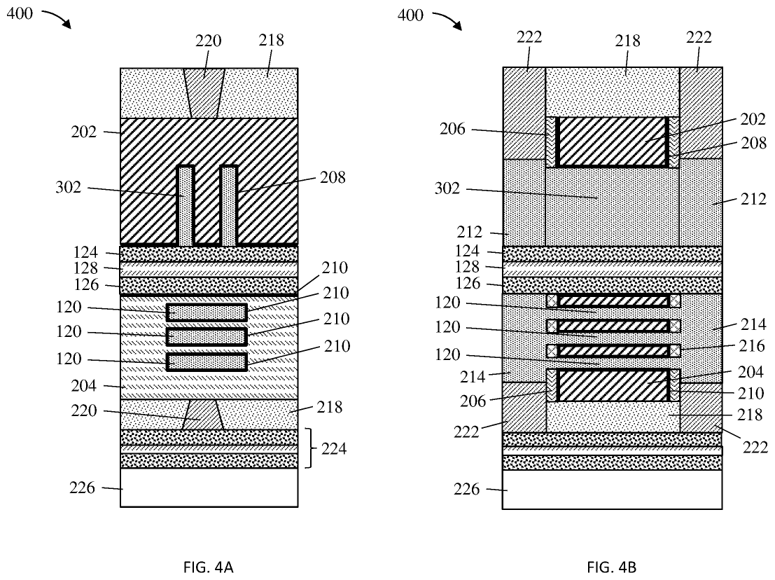

As shown in FIG. 3A, a semiconductor layer 302 is formed over the SOI layer 108 and the substrate 106. Observe that the semiconductor layer 302 has been formed in place of the nanosheet stack 104 shown in FIG. 1A. As will be discussed in greater detail below (FIGS. 4A and 4B), this configuration results in a hybrid SFET having a fin-type FET (finFET) vertically stacked over a nanosheet FET. In some embodiments of the invention, the first semiconductor wafer 300 and the second semiconductor wafer 102 are swapped, resulting in a hybrid SFET having a nanosheet FET vertically stacked over a finFET. The semiconductor layer 302 can be made of similar semiconductor materials as the substrate 106, such as, for example, silicon and silicon germanium. In some embodiments of the invention, the semiconductor layer 302 is formed to a thickness of about 10 to 100 nm, although other thicknesses are within the contemplated scope of the invention.

FIGS. 3C and 3D depict cross-sectional views of the first semiconductor wafer 300 and the second semiconductor wafer 102, respectively, after a processing operation according to one or more embodiments of the invention. As shown FIGS. 3C and 3D, the insulator layers 124 and 126 can be formed on surfaces of the semiconductor layer 302 and the second nanosheet stack 114, respectively. As further shown FIG. 3C, the first semiconductor wafer 300 can be flipped so that the insulator layer 124 is oriented towards the second semiconductor wafer 102.

FIG. 3E depicts a cross-sectional view of the first semiconductor wafer 300 and the second semiconductor wafer 102 after a wafer bonding operation according to one or more embodiments of the invention. As shown FIG. 3E, the bonding layer 128 can be bonded to opposing surfaces of the insulator layers 124 and 126, thereby bonding the first semiconductor wafer 300 to the second semiconductor wafer 102. The bonding layer 128 can include one or more of an oxide, a nitride, silicon nitride, SiOC, and SiBCN. In some embodiments of the invention, the bonding layer 128 includes a bonding oxide formed at a low temperature (i.e., less than 400 degrees Celsius). In some embodiments of the invention, one or both of the optional insulator layers 124 and 126 are skipped and the bonding layer 128 is bonded directly to one or both of the semiconductor layer 302 and/or the nanosheet stack 114. The surface(s) upon which the bonding layer 128 is formed can be optionally pretreated in a similar manner as discussed with respect to FIG. 1E.

FIG. 3F depicts a cross-sectional view of the first semiconductor wafer 300 and the second semiconductor wafer 102 after a processing operation according to one or more embodiments of the invention. As shown FIG. 3F, the bonding layer 128 can be annealed at an intermediate temperature (e.g., 700 degrees Celsius RTA, 500-600C furnace anneal, etc.). Annealing cures the bonding layer 128, improving oxide quality.

In some embodiments of the invention, the SOI layer 108, the substrate 106, and portions of the semiconductor layer 302 are removed. The SOI layer 108, the substrate 106, and portions of the semiconductor layer 302 can be removed using, for example, CMP, wafer grinding, or a combination of wet and/or dry etches.

After wafer grinding (or CMP, etc.) is complete, the combined first semiconductor wafer 300 and second semiconductor wafer 102 can be finalized using known FEOL, MOL, and BEOL processes to define the final SFET device. For example, the final SFET device can be assembled by building a first transistor using the exposed semiconductor layer 302, bonding a third wafer to the first transistor, flipping over the combined wafer, removing the bottom substrate to expose the nanosheet stack 114, and building the second transistor using the exposed nanosheet stack 114. FIGS. 4A and 4B depict cross-sectional views (parallel to gate and across gate, respectively) of an SFET 400 formed after completing the wafer bonding process discussed previously with respect to FIGS. 3A to 3F.

As shown in FIGS. 4A and 4B, the SFET 400 includes the semiconductor layer 302 and the semiconductor layers 120, the bonding layer 128, and the insulator layers 124, 126. Known FEOL processes have been carried out in a similar manner as discussed previously with respect to FIGS. 2A and 2B to form various structures, such as the top gate 202, the bottom gate 204, gate spacers 206, gate dielectrics 208, 210, top source and drain regions 212, bottom source and drain regions 214, inner spacers 216, ILD 218, gate contacts 220, source/drain contacts 222, the second bonding structure 224, and the wafer 226, each configured and arranged as shown.

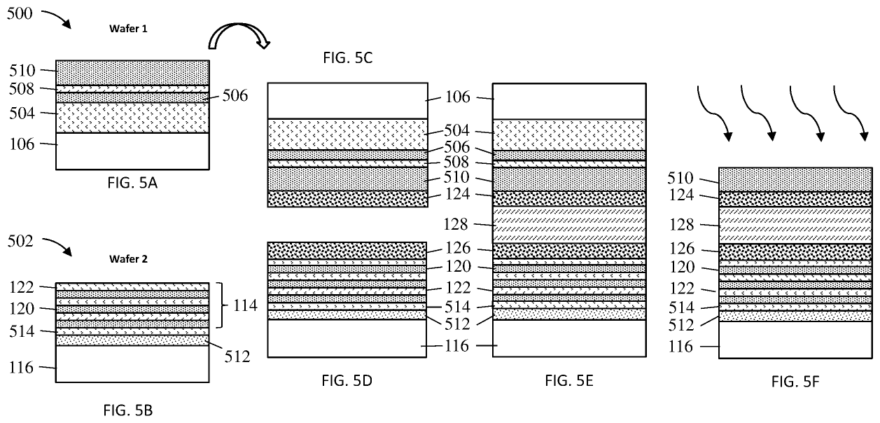

FIGS. 5A and 5B depict cross-sectional views of a first semiconductor wafer 500 (“Wafer 1”) and a second semiconductor wafer 502 (“Wafer 2”), respectively, after an initial set of fabrication operations have been applied as part of a method of fabricating a final semiconductor device according to one or more embodiments of the invention. FIGS. 5A and 5B illustrate a yet another embodiment to that shown in FIGS. 1A and 1B, except that the first semiconductor wafer 500 has been swapped for the first semiconductor wafer 100 and the second semiconductor wafer 502 has been swapped for the second semiconductor wafer 102.

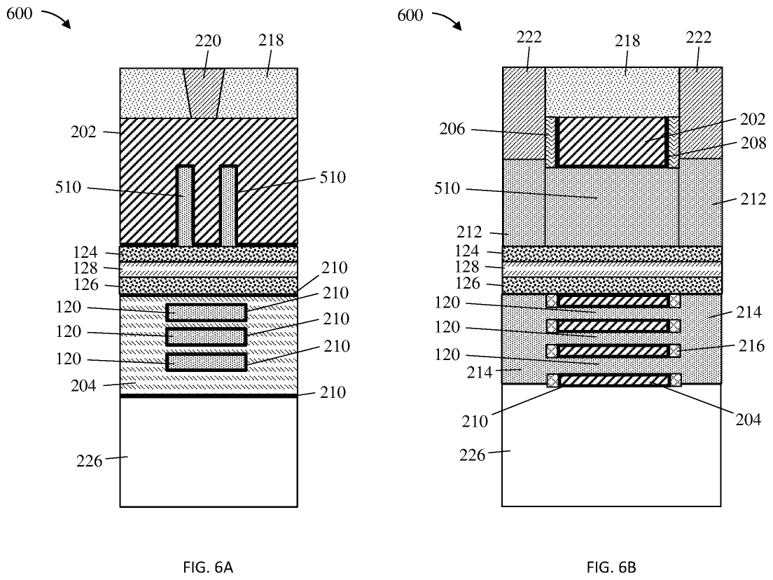

As shown in FIG. 5A, a first sacrificial layer 504 is formed over the substrate 106, a semiconductor layer 506 is formed over the first sacrificial layer 504, a second sacrificial layer 508 is formed over the semiconductor layer 506, and a second semiconductor layer 510 is formed over the second sacrificial layer 508. Observe that the semiconductor layers 506 and 510 have been formed in place of the nanosheet stack 104 shown in FIG. 1A. As will be discussed in greater detail below (FIGS. 6A and 6B), this configuration results in a hybrid SFET having a finFET vertically stacked over a nanosheet FET. In some embodiments of the invention, the first semiconductor wafer 500 and the second semiconductor wafer 502 are swapped, resulting in a hybrid SFET having a nanosheet FET vertically stacked over a finFET.

The semiconductor layers 506 and 510 can be made of similar semiconductor materials as the substrate 106, such as, for example, silicon and silicon germanium. In some embodiments of the invention, the semiconductor layer 506 is formed to a first thickness and the semiconductor layer 510 is formed to a second, greater thickness. For example, the semiconductor layer 506 can be formed to a thickness of about 10 to 30 nm and the semiconductor layer 510 can be formed to a thickness 10 to 120 nm greater (e.g., 20 to 150 nm), although other thicknesses are within the contemplated scope of the invention.

The sacrificial layers 504 and 508 can be made of similar materials as the sacrificial layers 112, such as, for example, silicon germanium. In some embodiments of the invention, the sacrificial layer 504 is formed to a first thickness and the sacrificial layer 508 is formed to a second, lesser thickness. For example, the sacrificial layer 504 can be formed to a thickness of about 10 to 100 nm and the sacrificial layer 508 can be formed to a thickness 20 to 60 nm, although other thicknesses are within the contemplated scope of the invention.

The second semiconductor wafer 502 can be formed in a similar manner as the second semiconductor wafer 102 shown in FIG. 1B, except that the SOI layer 18 has been replaced with additional sacrificial layers 512 and 514. The sacrificial layers 512 and 514 can be made of similar materials as the sacrificial layers 122, except that the sacrificial layer 512 material is selected to provide etch selectivity with respect to the sacrificial layer 514, the sacrificial layers 122, and the semiconductor layers 120. For example, in embodiments where the semiconductor layers 120 are silicon nanosheets and the sacrificial layers 122 and 514 are silicon germanium nanosheets, the sacrificial layer 512 can be silicon germanium layers having a germanium concentration that is greater than the germanium concentration in the sacrificial layers 122 and 514. For example, if the sacrificial layers 122 and 514 are silicon germanium having a germanium concentration of 5 percent (sometimes referred to as SiGe5), the sacrificial layer 512 can be silicon germanium having a germanium concentration of about 25 (SiGe25), although other germanium concentrations are within the contemplated scope of the invention. In some embodiments of the invention, the sacrificial layer 512 has a thickness of about 8 nm to about 50 nm, for example 10 nm, although other thicknesses are within the contemplated scope of the invention. In some embodiments of the invention, an additional semiconductor layer (not separately shown) is formed on the topmost sacrificial layer of the sacrificial layers 122.

FIGS. 5C and 5D depict cross-sectional views of the first semiconductor wafer 500 and the second semiconductor wafer 502, respectively, after a processing operation according to one or more embodiments of the invention. As shown FIGS. 5C and 5D, the insulator layers 124 and 126 can be formed on surfaces of the second semiconductor layer 510 and the second nanosheet stack 114, respectively. As further shown FIG. 5C, the first semiconductor wafer 500 can be flipped so that the insulator layer 124 is oriented towards the second semiconductor wafer 502.

FIG. 5E depicts a cross-sectional view of the first semiconductor wafer 500 and the second semiconductor wafer 502 after a wafer bonding operation according to one or more embodiments of the invention. As shown FIG. 5E, the bonding layer 128 can be bonded to opposing surfaces of the insulator layers 124 and 126, thereby bonding the first semiconductor wafer 500 to the second semiconductor wafer 502. The bonding layer 128 can include one or more of an oxide, a nitride, silicon nitride, SiOC, and SiBCN. In some embodiments of the invention, the bonding layer 128 includes a bonding oxide formed at a low temperature (i.e., less than 400 degrees Celsius). In some embodiments of the invention, one or both of the optional insulator layers 124 and 126 are skipped and the bonding layer 128 is bonded directly to one or both of the second semiconductor layer 510 and/or the nanosheet stack 114. The surface(s) upon which the bonding layer 128 is formed can be optionally pretreated in a similar manner as discussed with respect to FIG. 1E.

FIG. 5F depicts a cross-sectional view of the first semiconductor wafer 500 and the second semiconductor wafer 502 after a processing operation according to one or more embodiments of the invention. As shown FIG. 5F, the bonding layer 128 can be annealed at an intermediate temperature (e.g., 700 degrees Celsius RTA, 500-600C furnace anneal, etc.). Annealing cures the bonding layer 128, improving oxide quality. In some embodiments of the invention, the substrate 106, the first sacrificial layer 504, the semiconductor layer 506, and the second sacrificial layer 508 are removed using, for example, CMP, wafer grinding, or a combination of wet and/or dry etches.

After wafer grinding (or CMP, etc.) is complete, the combined first semiconductor wafer 500 and second semiconductor wafer 502 can be finalized using known FEOL, MOL, and BEOL processes to define the final SFET device. In some embodiments of the invention, the final SFET device can be assembled by concurrently building a first transistor using the exposed second semiconductor layer 510 and a second transistor using the exposed nanosheet stack 114 (i.e., without a third wafer bonding process, in contrast to the devices shown in FIGS. 2A, 2B, 4A, and 4B). FIGS. 6A and 6B depict cross-sectional views (parallel to gate and across gate, respectively) of an SFET 600 formed where the top transistors and bottom transistors are built concurrently without another wafer bonding process.

As shown in FIGS. 6A and 6B, the SFET 600 includes the second semiconductor layer 510 and the semiconductor layers 120, the bonding layer 128, and the insulator layers 124, 126. Known FEOL processes have been carried out in a similar manner as discussed previously with respect to FIGS. 2A and 2B to form various structures, such as the top gate 202, the bottom gate 204, gate spacers 206, gate dielectrics 208, 210, top source and drain regions 212, bottom source and drain regions 214, inner spacers 216, ILD 218, gate contacts 220, source/drain contacts 222, and the wafer 226, each configured and arranged as shown. Observe that, in contrast to the SFET 400 shown in FIGS. 4A and 4B, the wafer 226 is formed directly on the gate dielectric 210, the bottom source and drain regions 214, and the inner spacers 216. In this configuration the wafer 226 can serve as a handling wafer or as a substrate for additional processing (FEOL, MOL, or BEOL, as desired).

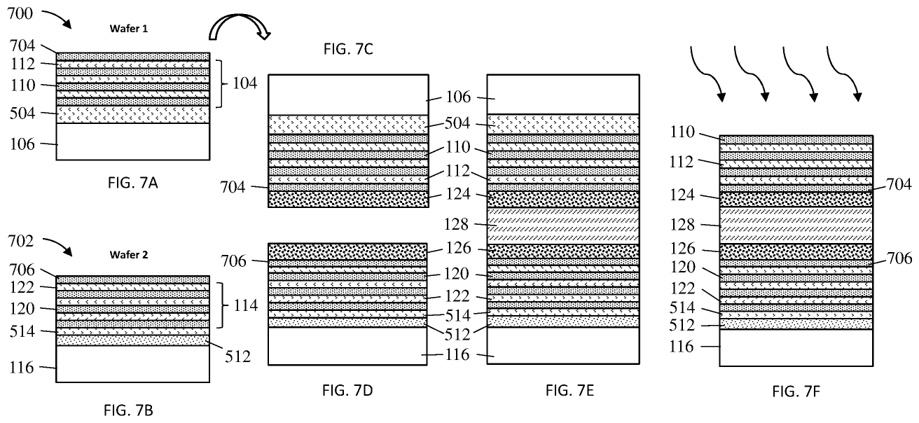

FIGS. 7A and 7B depict cross-sectional views of a first semiconductor wafer 700 (“Wafer 1”) and a second semiconductor wafer 702 (“Wafer 2”), respectively, after an initial set of fabrication operations have been applied as part of a method of fabricating a final semiconductor device according to one or more embodiments of the invention. FIGS. 7A and 7B illustrate a yet another embodiment to that shown in FIGS. 1A and 1B, except that the first semiconductor wafer 700 has been swapped for the first semiconductor wafer 100 and the second semiconductor wafer 702 has been swapped for the second semiconductor wafer 102.

The first semiconductor wafer 700 can be formed in a similar manner as the first semiconductor wafer 100, except that the SOI layer 108 has been replaced with the first sacrificial layer 504 (see FIG. 5) and a topmost semiconductor layer 704 is formed on the nanosheet stack 104. The second semiconductor wafer 702 can be formed in a similar manner as the second semiconductor wafer 502 (FIG. 5), except that a topmost semiconductor layer 706 is formed on the nanosheet stack 114. The semiconductor layers 704 and 706 can be made of similar semiconductor materials as the substrate 106, such as, for example, silicon and silicon germanium.

FIGS. 7C and 7D depict cross-sectional views of the first semiconductor wafer 700 and the second semiconductor wafer 702, respectively, after a processing operation according to one or more embodiments of the invention. As shown FIGS. 7C and 7D, the insulator layers 124 and 126 can be formed on surfaces of the second semiconductor layers 704 and 706, respectively. As further shown FIG. 7C, the first semiconductor wafer 700 can be flipped so that the insulator layer 124 is oriented towards the second semiconductor wafer 702.

FIG. 7E depicts a cross-sectional view of the first semiconductor wafer 700 and the second semiconductor wafer 702 after a wafer bonding operation according to one or more embodiments of the invention. As shown FIG. 7E, the bonding layer 128 can be bonded to opposing surfaces of the insulator layers 124 and 126, thereby bonding the first semiconductor wafer 700 to the second semiconductor wafer 702. The bonding layer 128 can include one or more of an oxide, a nitride, silicon nitride, SiOC, and SiBCN. In some embodiments of the invention, the bonding layer 128 includes a bonding oxide formed at a low temperature (i.e., less than 400 degrees Celsius). In some embodiments of the invention, one or both of the optional insulator layers 124 and 126 are skipped and the bonding layer 128 is bonded directly to one or both of the semiconductor layers 704 and 706. The surface(s) upon which the bonding layer 128 is formed can be optionally pretreated in a similar manner as discussed with respect to FIG. 1E.

FIG. 7F depicts a cross-sectional view of the first semiconductor wafer 700 and the second semiconductor wafer 702 after a processing operation according to one or more embodiments of the invention. As shown FIG. 7F, the bonding layer 128 can be annealed at an intermediate temperature (e.g., 700 degrees Celsius RTA, 500-600C furnace anneal, etc.). Annealing cures the bonding layer 128, improving oxide quality. In some embodiments of the invention, the substrate 106 and the first sacrificial layer 504 are removed using, for example, CMP, wafer grinding, or a combination of wet and/or dry etches.

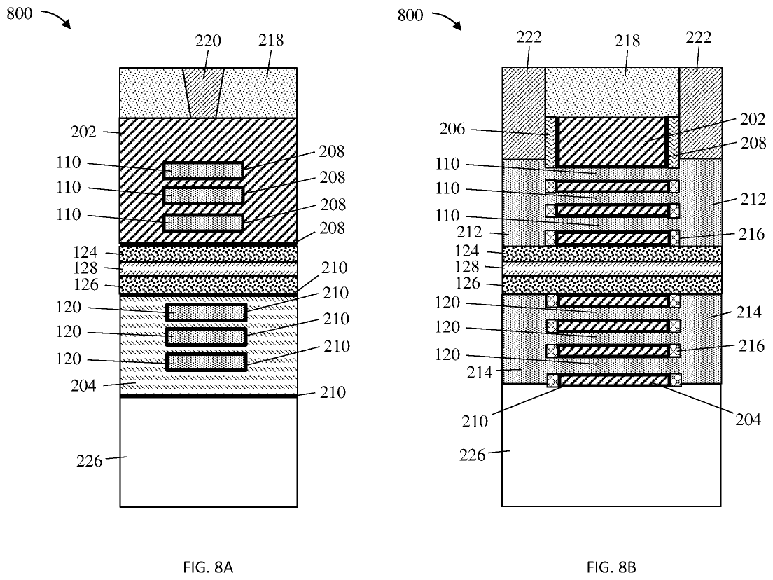

After wafer grinding (or CMP, etc.) is complete, the combined first semiconductor wafer 700 and second semiconductor wafer 702 can be finalized using known FEOL, MOL, and BEOL processes to define the final SFET device. FIGS. 8A and 8B depict cross-sectional views (parallel to gate and across gate, respectively) of an SFET 800 formed where the top transistors and bottom transistors are built without another wafer bonding process.

As shown in FIGS. 8A and 8B, the SFET 800 includes the semiconductor layers 110 and 120, the bonding layer 128, and the insulator layers 124, 126. Known FEOL processes have been carried out in a similar manner as discussed previously with respect to FIGS. 2A and 2B to form various structures, such as the top gate 202, the bottom gate 204, gate spacers 206, gate dielectrics 208, 210, top source and drain regions 212, bottom source and drain regions 214, inner spacers 216, ILD 218, gate contacts 220, source/drain contacts 222, and the wafer 226, each configured and arranged as shown. Observe that, in contrast to the SFET 400 shown in FIGS. 4A and 4B, the wafer 226 is formed directly on the gate dielectric 210, the bottom source and drain regions 214, and the inner spacers 216. In this configuration the wafer 226 can serve as a handling wafer or as a substrate for additional processing (FEOL, MOL, or BEOL, as desired).

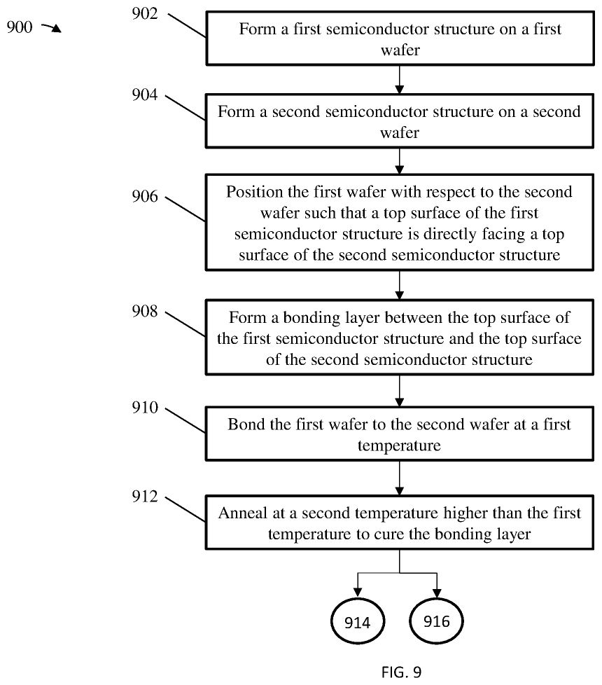

FIG. 9 depicts a flow diagram illustrating a method 900 that leverages wafer bonding techniques to provide SFETs with high-quality N/P junction isolation according to one or more embodiments of the invention. As shown at block 902, a first semiconductor structure is formed on a first wafer. At block 904, a second semiconductor structure is formed on a second wafer.

In some embodiments of the invention, the first semiconductor structure comprises channel layer(s) of a first transistor type and the second semiconductor structure comprises channel layer(s) of a second transistor type. In some embodiments of the invention, the first transistor type comprises one of a fin-type field effect transistor and a nanosheet transistor and the second transistor type comprises one of a nanosheet transistor and a fin-type field effect transistor.

In some embodiments of the invention, the first semiconductor structure comprises a first transistor type having a first crystalline orientation and the second semiconductor structure comprises the first transistor type having a second crystalline orientation. In some embodiments of the invention, the first transistor type comprises one of a fin-type field effect transistor and a nanosheet transistor, the first crystalline orientation comprises a <110> orientation, and the second crystalline orientation comprises a <100> orientation.

At block 906, the first wafer is positioned (rotated) with respect to the second wafer such that a top surface of the first semiconductor structure is directly facing a top surface of the second semiconductor structure.

At block 908, a bonding layer is formed between the top surface of the first semiconductor structure and the top surface of the second semiconductor structure. At block 910, the first wafer is bonded to the second wafer at a first temperature (the bonding temperature). In some embodiments of the invention, the first temperature comprises a temperature below 400 degrees Celsius.

At block 912, the combined wafer structure is annealed at a second temperature (the anneal temperature) to cure the bonding layer. In some embodiments of the invention, the second temperature is greater than the first temperature. In some embodiments of the invention, the second temperature comprises a temperature above 400 degrees Celsius and below 1000 degrees Celsius.

The method 900 can further include forming a first insulator layer between the first semiconductor structure and the bonding layer and forming a second insulator layer between the second semiconductor structure and the bonding layer. In some embodiments of the invention, the first insulator layer and the second insulator layer comprise high density plasma (HDP) oxides.

In some embodiments of the invention, a surface of the first insulator layer and a surface of the second insulator layer are pretreated. In some embodiments of the invention, pretreating comprises one or more of a deionized (DI) water treatment, an argon or oxygen plasma treatment, and an ultraviolet (UV) cure.

In some embodiments of the invention, the first semiconductor structure comprises a fin-type semiconductor structure and the second semiconductor structure comprises a gate all around (GAA) nanosheet structure (or vice versa). In some embodiments of the invention, the fin-type semiconductor structure comprises one or more semiconductor fins and a first gate formed over channel regions of the one or more semiconductor fins. In some embodiments of the invention, a bonding layer is formed over the semiconductor fins. In some embodiments of the invention, the GAA nanosheet structure comprises a nanosheet stack formed over the bonding layer and a second gate formed over channel regions of the nanosheet stack.

In some embodiments of the invention, the GAA nanosheet structure comprises an NFET and the fin-type semiconductor structure comprises a PFET (or vice versa). In some embodiments of the invention, the one or more semiconductor fins comprise a first crystalline orientation and the nanosheet stack comprises a second crystalline orientation. In some embodiments of the invention, the first crystalline orientation comprises a <110> crystalline orientation and the second crystalline orientation comprises a <100> crystalline orientation.

In some embodiments of the invention, the first semiconductor structure comprises a first GAA nanosheet structure and the second semiconductor structure comprises a second GAA nanosheet structure. In some embodiments of the invention, the first GAA nanosheet structure comprises a first nanosheet stack and a first gate formed over channel regions of the first nanosheet stack. In some embodiments of the invention, a bonding layer is formed over the first GAA nanosheet structure. In some embodiments of the invention, the second GAA nanosheet structure comprises a second nanosheet stack formed over the bonding layer and a second gate formed over channel regions of the second nanosheet stack.

In some embodiments of the invention, the first GAA nanosheet structure comprises an NFET and the second GAA nanosheet structure comprises a PFET (or vice versa). In some embodiments of the invention, the first GAA nanosheet structure comprises an NFET and the second GAA nanosheet structure comprises a PFET (or vice versa). In some embodiments of the invention, the first nanosheet stack comprises a first crystalline orientation and the second nanosheet stack comprises a second crystalline orientation. In some embodiments of the invention, the first crystalline orientation comprises a <110> crystalline orientation and the second crystalline orientation comprises a <100> crystalline orientation.

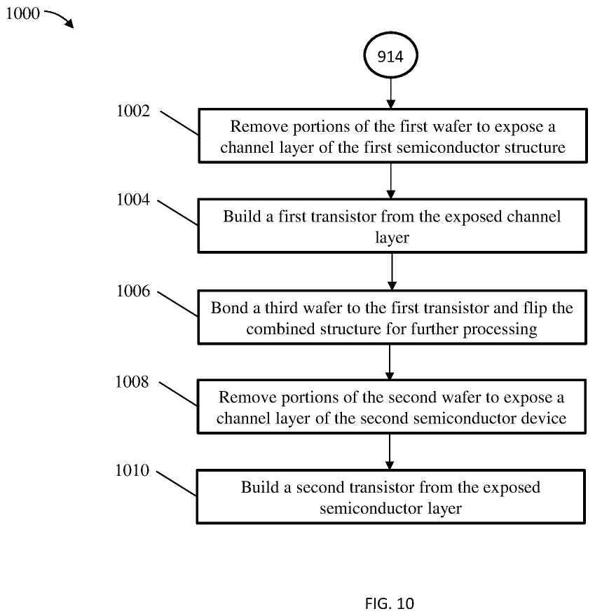

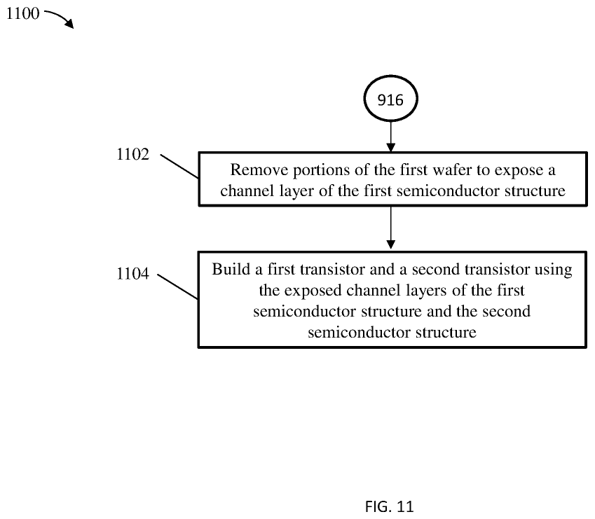

After annealing (block 912), the wafers can be further processed according to one of the methods 1000 and 1100 depicted in FIGS. 10 and 11, respectively, to complete building the stacked transistors of the final SFET structure.

FIG. 10 depicts a flow diagram illustrating a method 1000 that leverages wafer bonding techniques to provide SFETs with high-quality N/P junction isolation according to one or more embodiments of the invention. As shown at block 1002, portions of the first wafer (or alternatively, the second wafer) are removed from the combined wafer structure to expose a top surface of an underlying channel layer(s) of the first semiconductor structure (e.g., the semiconductor layers 110 of the nanosheet stack 104 as shown in FIG. 1F) using, for example, wafer grinding or CMP.

At block 1004, a first transistor is built using the exposed channel layers. The first transistor can be a nanosheet transistor, finFET, or any other transistor type, depending on the configuration of the underlying semiconductor layers.

At block 1006, a third wafer is bonded to the first transistor (one end of the combined wafer structure) and the combined wafer structure is flipped for further processing. The third wafer can be bonded to the first transistor in a same manner as discussed previously with respect to the first and second wafers (e.g., via a bonding layer and anneal according to one or more embodiments).

At block 1008, portions of the second wafer (or alternatively, the first wafer) are removed from the combined wafer structure to expose a top surface of an underlying channel layer(s) of the second semiconductor structure (e.g., the semiconductor layers 120 of the nanosheet stack 114 as shown in FIG. 1F) using, for example, wafer grinding or CMP.

At block 1010, a second transistor is built using the exposed channel layers. The second transistor can be a nanosheet transistor, finFET, or any other transistor type, depending on the configuration of the underlying semiconductor layers. FIGS. 2A and 2B depict cross-sectional views (parallel to gate and across gate, respectively) of an SFET 200 formed after completing the process shown in FIG. 10. The final SFET structure can then be finalized using known FEOL, MOL, and BEOL processes.

FIG. 11 depicts a flow diagram illustrating a method 1100 that leverages wafer bonding techniques to provide SFETs with high-quality N/P junction isolation according to one or more embodiments of the invention. As shown at block 1102, portions of the first wafer (or alternatively, the second wafer) are removed from the combined wafer structure to expose a top surface of an underlying channel layer(s) of the first semiconductor structure using, for example, wafer grinding or CMP.

At block 1104, a first transistor and a second transistor are built concurrently (or sequentially) using the exposed channel layers of the first semiconductor structure and the second semiconductor structure, respectively. The first and second transistors can each be a nanosheet transistor, finFET, or any other transistor type, depending on the configuration of the underlying semiconductor layers. FIGS. 6A and 6B depict cross-sectional views (parallel to gate and across gate, respectively) of an SFET 600 formed after completing the process shown in FIG. 11. The final SFET structure can then be finalized using known FEOL, MOL, and BEOL processes.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop.

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a stacked semiconductor device, the method comprising:
forming a first semiconductor structure on a first wafer;
forming a second semiconductor structure on a second wafer;
positioning the first wafer with respect to the second wafer such that a top surface of the first semiconductor structure is directly facing a top surface of the second semiconductor structure;
forming a bonding layer between the top surface of the first semiconductor structure and the top surface of the second semiconductor structure;
bonding the first wafer to the second wafer at a first temperature; and
annealing at a second temperature to cure the bonding layer, wherein the second temperature is greater than the first temperature.

2. The method of claim 1, wherein the first semiconductor structure comprises a channel layer of a first transistor type and the second semiconductor structure comprises a channel layer of a second transistor type.

3. The method of claim 2, wherein:
the first transistor type comprises one of a fin-type field effect transistor and a nanosheet transistor; and
the second transistor type comprises one of a nanosheet transistor and a fin-type field effect transistor.

4. The method of claim 1, wherein the first semiconductor structure comprises a first transistor type having a first crystalline orientation and the second semiconductor structure comprises the first transistor type having a second crystalline orientation.

5. The method of claim 4, wherein the first transistor type comprises one of a fin-type field effect transistor and a nanosheet transistor, the first crystalline orientation comprises a <110> orientation, and the second crystalline orientation comprises a <100> orientation.

6. The method of claim 1 further comprising:
forming a first insulator layer between the first semiconductor structure and the bonding layer; and
forming a second insulator layer between the second semiconductor structure and the bonding layer.

7. The method of claim 6, wherein the first insulator layer and the second insulator layer comprise high density plasma (HDP) oxides.

8. The method of claim 6 further comprising pretreating a surface of the first insulator layer and a surface of the second insulator layer.

9. The method of claim 8, wherein pretreating comprises one or more of a deionized (DI) water treatment, an argon or oxygen plasma treatment, and an ultraviolet (UV) cure.

10. The method of claim 1, wherein:
the first temperature comprises a temperature below 400 degrees Celsius; and
the second temperature comprises a temperature above 400 degrees Celsius and below 1000 degrees Celsius.

11. A stacked semiconductor device comprising:
a fin-type semiconductor structure, the fin-type semiconductor structure comprising one or more semiconductor fins and a first gate formed over channel regions of the one or more semiconductor fins;
a bonding layer over the fin-type semiconductor structure; and
a gate all around (GAA) nanosheet structure, the GAA nanosheet structure comprising a nanosheet stack formed over the bonding layer and a second gate formed over channel regions of the nanosheet stack.

12. The semiconductor device of claim 11, wherein the GAA nanosheet structure comprises an NFET and the fin-type semiconductor structure comprises a PFET.

13. The semiconductor device of claim 11, wherein the GAA nanosheet structure comprises a PFET and the fin-type semiconductor structure comprises an NFET.

14. The semiconductor device of claim 11, wherein the one or more semiconductor fins comprise a first crystalline orientation and the nanosheet stack comprises a second crystalline orientation.

15. The semiconductor device of claim 14, wherein the first crystalline orientation comprises a <110> crystalline orientation and the second crystalline orientation comprises a <100> crystalline orientation.

16. A stacked semiconductor device comprising:
a first gate all around (GAA) nanosheet structure, the first GAA nanosheet structure comprising a first nanosheet stack and a first gate formed over channel regions of the first nanosheet stack;
a bonding layer over the first GAA nanosheet structure; and
a second GAA nanosheet structure, the second GAA nanosheet structure comprising a second nanosheet stack formed over the bonding layer and a second gate formed over channel regions of the second nanosheet stack.

17. The semiconductor device of claim 16, wherein the first GAA nanosheet structure comprises a PFET and the second GAA nanosheet structure comprises an NFET.

18. The semiconductor device of claim 16, wherein the first GAA nanosheet structure comprises an NFET and the second GAA nanosheet structure comprises a PFET.

19. The semiconductor device of claim 18, wherein the first nanosheet stack comprises a first crystalline orientation and the second nanosheet stack comprises a second crystalline orientation.

20. The semiconductor device of claim 19, wherein the first crystalline orientation comprises a <100> crystalline orientation for the NFET and the second crystalline orientation comprises a <110> crystalline orientation for the PFET.
